(19) United States
(12) Patent Application Publication
(10) Pub. No.: US 2025/0199372 A1
(43) Pub. Date: Jun. 19, 2025

(54) OPTICAL PATH CONTROL MEMBER AND DISPLAY DEVICE COMPRISING SAME

(71) Applicant: LG INNOTEK CO., LTD., Seoul (KR)

(72) Inventors: Jun LEE, Seoul (KR); Jin Mi NOH, Seoul (KR); Jong Sik LEE, Seoul (KR)

(21) Appl. No.: 18/847,970

(22) PCT Filed: Mar. 2, 2023
(86) PCT No.: PCT/KR2023/002866

§ 371 Date: Sep. 17, 2024

(30) Foreign Application Priority Data
Mar. 17, 2022 (KR) 10-2022-0033231

(51) Int. Cl. G02F 1/167; G02F 1/1335; G02F 1/13357; G02F 1/16766; G02F 1/1677

(52) U.S. Cl. CPC G02F 1/167; G02F 1/133512; G02F 1/133603; G02F 1/16766; G02F 1/1677

(57) ABSTRACT

An optical path control member according to an embodiment includes a first substrate; a first electrode disposed on the first substrate; a second substrate disposed on the first substrate; a second electrode disposed under the second substrate; a light conversion unit disposed between the first electrode and the second electrode; a connection electrode including a first connection electrode formed by exposing the first electrode and a second connection electrode formed by exposing the second electrode; and a printed circuit board electrically connected to the first connection electrode and the second connection electrode, wherein an adhesive layer disposed between the connection electrode and the printed circuit board, and the adhesive layer includes an isotropic conductive adhesive layer.

### TECHNICAL FIELD

An embodiment relates to an optical path control member and a display device comprising the same.

### BACKGROUND ART

A light blocking film blocks transmitting of light from a light source, and is attached to a front surface of a display panel which is a display device used for a mobile phone, a notebook, a tablet PC, a vehicle navigation device, a vehicle touch, etc., so that the light blocking film adjusts a viewing angle of light according to an incident angle of light to express a clear image quality at a viewing angle needed by a user when the display transmits a screen.

In addition, the light blocking film may be used for the window of a vehicle, building or the like to shield outside light partially to prevent glare, or to prevent the inside from being visible from the outside.

That is, the light blocking film may be an optical path control member that controls the movement path of light to block light in a specific direction and transmit light in a specific direction. Accordingly, it is possible to control the viewing angle of the user by controlling a transmission angle of the light by the light blocking film.

Meanwhile, such a light blocking film may be divided into a light blocking film that can always control the viewing angle regardless of the surrounding environment or the user's environment and a switchable light blocking film that allow the user to turn on/off the viewing angle control according to the surrounding environment or the user's environment.

Such a switchable light blocking film may be implemented by filling a light conversion material including particles that can move as a voltage is applied to the receiving part and a dispersion that disperses the particles, and changing the receiving part to a light transmitting part and a light blocking part by dispersion and aggregation of the particles.

The switchable light blocking film may be connected to a printed circuit board. The switchable light blocking film may be connected to another member by the printed circuit board. Alternatively, an operation of the switchable light blocking film may be controlled by a chip of the printed circuit board.

The switchable light blocking film and the printed circuit board may be connected by a conductive adhesive layer. If a thickness of the adhesive layer increases, a thickness of the switchable light blocking film may increase. In addition, a manufacturing process may become difficult.

Accordingly, in order to solve the above problems, an optical path control member having a new structure is required.

### DISCLOSURE

### Technical Problem

The embodiment relates to an optical path control member having a reduced thickness and a display device including the same.

The embodiment relates to an optical path control member that can be easily manufactured and a display device including the same.

### Technical Solution

An optical path control member according to an embodiment includes a first substrate; a first electrode disposed on the first substrate; a second substrate disposed on the first substrate; a second electrode disposed under the second substrate; a light conversion unit disposed between the first electrode and the second electrode; a connection electrode including a first connection electrode formed by exposing the first electrode and a second connection electrode formed by exposing the second electrode; and a printed circuit board electrically connected to the first connection electrode and the second connection electrode, wherein an adhesive layer disposed between the connection electrode and the printed circuit board, and the adhesive layer includes an isotropic conductive adhesive layer.

### Advantageous Effects

The optical path control member according to an embodiment includes an adhesive layer. The adhesive layer electrically connects a first electrode and a printed circuit board. Also, the adhesive layer electrically connects a second electrode and the printed circuit board.

The adhesive layer includes an isotropic conductive adhesive layer. Accordingly, the adhesive layer has conductivity in all directions. Accordingly, electrical connection characteristics between the first electrode and a pad part of the printed circuit board are improved.

In addition, the adhesive layer is disposed as a single layer. Accordingly, a thickness of the adhesive layer is reduced. Accordingly, a thickness of the optical path control member is reduced.

Also, the adhesive layer includes regions having different thicknesses. Specifically, the adhesive layer is also disposed in a region between the pad parts. Accordingly, a contact area of the adhesive layer is increased. Accordingly, adhesion and electrical connection characteristics between the electrode and the printed circuit board are improved.

### DESCRIPTION OF DRAWINGS

FIG. 1 is a view showing a perspective view of an optical path control member according to an embodiment.

FIGS. 2 and 3 are cross-sectional views taken along line A-A′ of FIG. 1.

FIGS. 4 and 5 are combined cross-sectional views of an optical path control member and a printed circuit board according to an embodiment.

FIGS. 6 and 7 are cross-sectional views of a display device to which an optical path control member according to an embodiment is applied.

FIGS. 8 to 10 are views for describing one embodiment of the display device to which the optical path control member according to the embodiment is applied.

### MODES OF THE INVENTION

Hereinafter, embodiments of the present invention will be described in detail with reference to the accompanying drawings. However, the spirit and scope of the present invention is not limited to a part of the embodiments described, and may be implemented in various other forms, and within the spirit and scope of the present invention, one or more of the elements of the embodiments may be selectively combined and replaced.

In addition, unless expressly otherwise defined and described, the terms used in the embodiments of the present invention (including technical and scientific terms) may be construed the same meaning as commonly understood by one of ordinary skill in the art to which this invention belongs, and the terms such as those defined in commonly used dictionaries may be interpreted as having a meaning that is consistent with their meaning in the context of the relevant art.

In addition, the terms used in the embodiments of the present invention are for describing the embodiments and are not intended to limit the present invention. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present invention, the terms such as first, second, A, B, (a), and (b) may be used. These terms are only used to distinguish the elements from other elements, and the terms are not limited to the essence, order, or order of the elements.

In addition, when an element is described as being “connected”, or “coupled” to another element, it may include not only when the element is directly “connected” to, or “coupled” to other elements, but also when the element is “connected”, or “coupled” by another element between the element and other elements.

Further, when described as being formed or disposed “on (over)” or “under (below)” of each element, the “on (over)” or “under (below)” may include not only when two elements are directly connected to each other, but also when one or more other elements are formed or disposed between two elements.

Furthermore, when expressed as “on (over)” or “under (below)”, it may include not only the upper direction but also the lower direction based on one element.

Hereinafter, an optical path control member according to an embodiment will be described with reference to the drawings.

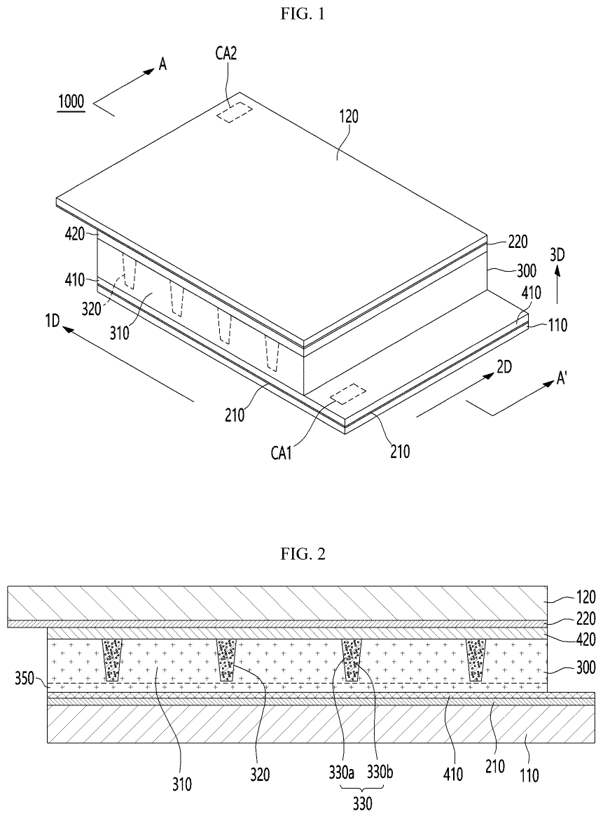

FIGS. 1 to 3 are views for explaining an optical path control member according to an embodiment.

Referring to FIG. 1, an optical path control member 1000 according to an embodiment may include a first substrate 110, a second substrate 120, a first electrode 210, a second electrode 220, and a light conversion unit 300.

The first substrate 110 may support the first electrode 210. The first substrate 110 may be rigid or flexible. Additionally, the second substrate 120 supports the second electrode 220.

In addition, at least one of the first substrate 110 and the second substrate 120 may be transparent. For example, at least one of the first substrate 110 and the second substrate 120 may include a transparent substrate capable of transmitting light.

At least one of the first substrate 110 and the second substrate 120 may include glass, plastic, or a flexible polymer film. For example, the flexible polymer film may be made of any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC) film, polyvinyl alcohol (PVA) film, polyimide (PI) film, and polystyrene (PS), which is only an example, but the embodiment is not limited thereto.

In addition, at least one of the first substrate 110 and the second substrate 120 may be a flexible substrate having flexible characteristics.

In addition, at least one of the first substrate 110 and the second substrate 120 may be a curved or bended substrate. That is, the optical path control member including at least one of the first substrate 110 and the second substrate 120 may also be formed to have flexible, curved, or bent characteristics. Accordingly, the optical path control member according to the embodiment may be changed to various designs.

The first substrate 110 and the second substrate 120 may extend in a first direction 1A, a second direction 2A, and a third direction 3A.

The first direction 1D corresponds to a longitudinal or width direction of the first substrate 110 and the second substrate 120. The second direction 2D corresponds to the longitudinal or width direction of the first substrate 110 and the second substrate 120. Also, the second direction 2D extends in a direction different from the first direction 1D. The third direction 3D corresponds to a thickness direction of the first substrate 110 and the second substrate 120. Also, the third direction 3D extends in a direction different from the first direction 1D and the second direction 2D.

For example, the first direction 1D may be defined in a longitudinal direction of the first substrate 110 and the second substrate 120. Also, the second direction 2D may be defined in a width direction of the first substrate 110 and the second substrate 120. Also, the third direction 3D may be defined in a thickness direction of the first substrate 110 and the second substrate 120.

Alternatively, the first direction 1D may be defined in a width direction of the first substrate 110 and the second substrate 120. Also, the second direction 2D may be defined in a longitudinal direction of the first substrate 110 and the second substrate 120. Also, the third direction 3D may be defined in a thickness direction of the first substrate 110 and the second substrate 120.

Hereinafter, for convenience of description, the first direction 1D is defined in the longitudinal directions of the first substrate 110 and the second substrate 120. Also, the second direction 2D is defined in the width directions of the first substrate 110 and the second substrate 120. Also, the third direction 3D is defined in the thickness directions of the first substrate 110 and the second substrate 120.

The first substrate 110 and the second substrate 120 may have a thickness within a set range. For example, the first substrate 110 and the second substrate 120 may have a thickness of 25 μm to 150 μm.

The first electrode 210 may be disposed on one surface of the first substrate 110. In detail, the first electrode 210 may be disposed on an upper surface of the first substrate 110. That is, the first electrode 210 may be disposed between the first substrate 110 and the second substrate 120.

In addition, the second electrode 220 is disposed on one surface of the second substrate 120. Specifically, the second electrode 220 is disposed on a lower surface of the second substrate 120. That is, the second electrode 220 is disposed between the first substrate 110 and the second substrate 120 and faces the first electrode 210.

At least one of the first electrode 210 and the second electrode 220 may include a transparent conductive material. For example, at least one of the first electrode 210 and the second electrode 220 may include a conductive material having a light transmittance of about 80% or more. For example, at least one of the first electrode 210 and the second electrode 220 may include a metal oxide such as indium tin oxide, indium zinc oxide, copper oxide, tin oxide, zinc oxide, titanium oxide, etc.

The first electrode 210 and the second electrode 220 may have a thickness of 10 nm to 300 nm.

At least one of the first electrode 210 and the second electrode 220 may include various metals to realize low resistance. For example, at least one of the first electrode 210 and the second electrode 220 may include at least one metal of chromium (Cr), nickel (Ni), copper (Cu), aluminum (Al), silver (Ag), molybdenum (Mo). Gold (Au), titanium (Ti), and alloys thereof.

The first electrode 210 and the second electrode 220 may be disposed on the entire surface of one surface of the first substrate 110 and the second substrate 120, respectively. In detail, the first electrode 210 may be disposed as a surface electrode on one surface of the first substrate 110. Specifically, the first electrode 210 and the second electrode 220 may be disposed as surface electrodes on one surface of the first substrate 110 and the second substrate 120, respectively.

Alternatively, the first electrode 210 and the second electrode 220 may be disposed on one surfaces of the first substrate 110 and the second substrate 120, respectively, as pattern electrodes. That is, the first electrode 210 and the second electrode 220 may be disposed on one surfaces of the first substrate 110 and the second substrate 120, respectively, as a plurality of pattern electrodes spaced apart from each other.

In addition, at least one of the first electrode 210 and the second electrode 220 may be formed as a mesh-shaped electrode including an opening.

Accordingly, even if at least one of the first electrode 210 and the second electrode 220 includes metal, the electrode is not visually recognized from the outside. Accordingly, the user's visibility is improved. In addition, the optical path control member has an increased light transmittance by the openings. Accordingly, a luminance of the optical path control member is improved.

The optical path control member 1000 includes a connection region. Specifically, the optical path control member 1000 includes a first connection region CA1 disposed on the first substrate 110 and a second connection region CA2 disposed on the second substrate 120.

A first connection electrode is disposed in the first connection region CA1. A second connection electrode is disposed in the second connection region CA2. The first connection electrode is formed by partially exposing the first electrode. The second connection electrode is formed by partially exposing the second electrode.

Although FIG. 1 illustrates that the first connection region CA1 and the second connection region CA2 do not overlap in the third direction, an embodiment is not limited thereto, for example, the first substrate or the second substrate is disposed not to cross each other. Also, the first connection region CA1 and the second connection region CA2 may overlap in the third direction.

Each of the first connection region CAI and the second connection region CA2 is connected to an external printed circuit board 500. The printed circuit board 500 may be rigid or flexible.

Specifically, an adhesive layer is disposed on the first connection region CAI and the second connection region CA2. The printed circuit board 500 is disposed on the adhesive layer. Accordingly, the first connection region CA1 is connected to the printed circuit board 500. Also, the second connection region CA2 is connected to the printed circuit board 500.

The connection between the optical path control member 1000 and the printed circuit board 500 will be described in detail below.

A light conversion unit 300 is disposed between the first substrate 110 and the second substrate 120. Specifically, the light conversion unit 300 is disposed between the first electrode 210 and the second electrode 220.

A buffer layer 410 is disposed between the first electrode 210 and the light conversion unit 300. Accordingly, an adhesion between the first electrode 210 and the light conversion unit 300 including different materials is improved. Also, an adhesive layer 420 is disposed between the second electrode 220 and the light conversion unit 300. Accordingly, the second substrate 110 and the light conversion unit 300 are adhered to each other.

Thus, the first substrate 110, the second substrate 120, and the light conversion unit 300 are adhered by the buffer layer 410 and the adhesive layer 420.

The light conversion part 300 includes a plurality of partition wall parts 310 and a receiving part 320. Light conversion particles and a dispersion liquid are disposed in the receiving part 320. The light conversion particles move by an application of a voltage. A light transmission characteristic of the optical path control member is changed by a movement of the light conversion particles. Also, the dispersion liquid disperses the light conversion particles.

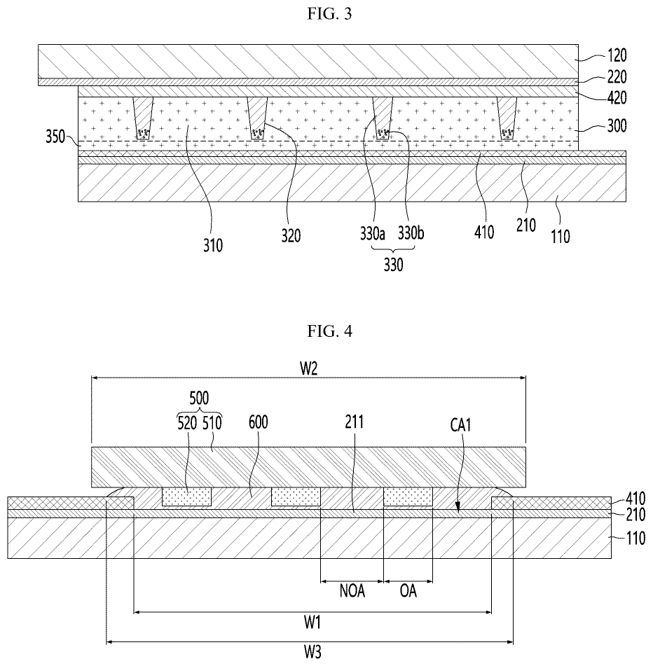

FIGS. 2 and 3 are cross-sectional views taken along line A-A′ of FIG. 1.

Referring to FIGS. 2 and 3, the light conversion unit 300 may include a partition wall part 310 and a receiving part 320.

The partition wall part 310 may be defined as a partition wall region that separates a plurality of receiving parts. The partition wall part 310 can transmit light. That is, light emitted from the direction of the first substrate 110 or the second substrate 120 may pass through the partition wall part.

The partition wall part 310 and the receiving part 320 may be arranged at different widths. For example, the width of the partition wall part 310 may be greater than the width of the receiving part 320.

In addition, the receiving part 320 may be formed in a shape in which the width is widened while extending from the first electrode 210 toward the second electrode 220.

The partition wall part 310 and the receiving part 320 may be arranged alternately. That is, each partition wall part 310 is disposed between the receiving parts 320 adjacent to each other. In addition, each receiving part 320 is disposed between the partition wall parts 310 adjacent to each other.

The partition wall part 310 may include a transparent material. The partition wall part 310 may include a material capable of transmitting light.

The partition wall part 310 may include a resin material. For example, the partition wall part 310 may include a photocurable resin material. For example, the partition wall part 310 may include UV resin or transparent photoresist resin. Alternatively, the partition wall part 310 may include urethane resin or acrylic resin.

The receiving part 320 may be formed to partially penetrate the light conversion unit 300. Accordingly, the receiving part 320 is disposed in contact with the adhesive layer 420. In addition, the receiving part 3200 is disposed to be spaced apart from the buffer layer 410. Accordingly, a base part 350 may be formed between the receiving part 320 and the buffer layer 410.

A light conversion material 330 may be disposed in the receiving part 320. The light conversion material 330 includes light conversion particles 330a and a dispersion liquid 330b in which the light conversion particles 330a are dispersed.

The dispersion liquid 330b may disperse the light conversion particles 330a. The dispersion liquid 330b may include a transparent material. The dispersion liquid 330b may include a non-polar solvent. In addition, the dispersion liquid 330b may include a light-transmitting material. For example, the dispersion 330b may include at least one of halocarbon oil, paraffin oil, and isopropyl alcohol.

The light conversion particles 330b are dispersed in the dispersion liquid 330a.

The light conversion particles 330a may include a material capable of absorbing light. That is, the light conversion particles 330a may be light absorbing particles. In addition, the light conversion particles 330a may have a color. For example, the light conversion particles 330a may have a black-based color. For example, the light conversion particles 330a may include carbon black particles.

The light conversion particles 330a may have a polarity by charging a surface thereof. For example, the surface of the light conversion particles 330a may be charged with a negative (−) charge. Accordingly, according to the application of the voltage, the light conversion particles 330a may move toward the first electrode 210 or the second electrode 220.

The light transmittance of the receiving part 320 is changed by the movement of the light conversion particle 330b. Accordingly, the receiving part 320 is changed into a light blocking part and a light transmitting part. Specifically, the light transmittance of the receiving part 320 is changed by the dispersion and aggregation of the light conversion particles 330b.

For example, the optical path member according to an embodiment is switched from a first mode to a second mode by a voltage applied to an electrode. Alternatively, the optical path control member is switched from the second mode to the first mode.

Specifically, in the first mode, the receiving part 320 serves as a light blocking part. Accordingly, light of a specific range of angle is blocked by the receiving part 320. That is, a viewing angle of the user viewed from an outside is narrowed. Accordingly, the optical path control member is driven in a privacy mode.

Also, in the second mode, the receiving part 320 becomes a light transmitting part. Accordingly, light is transmitted from both the partition wall part 310 and the receiving part 320. That is, the viewing angle of the user viewed from the outside is widened. Accordingly, the optical path control member is driven in a public mode.

The switching from the first mode to the second mode is implemented by the movement of the light conversion particle 330b. Specifically, a surface of the light conversion particle 330b is charged. The light conversion particle 330b is moved in a direction toward the first electrode or the second electrode according to a polarity of the surface.

For example, when a voltage is not applied to the optical path control member, the light conversion particles 330b are uniformly dispersed in the dispersion liquid 330a. Accordingly, the light of the receiving part 320 is blocked by the light conversion particles 330b. Accordingly, in the first mode, the receiving part 320 operates as a light blocking part.

Furthermore, when a voltage is applied to the optical path control member, the light conversion particles 330b move. For example, the light conversion particles 330b move in a direction toward one end or the other end of the receiving part 320 by the voltage applied from the first electrode 210 and the second electrode 220. That is, the light conversion particles 330b move in a direction toward the first electrode 210 or the second electrode 220.

For example, when a voltage is applied to the first electrode 210 and/or the second electrode 220, an electric field is formed between the first electrode 210 and the second electrode 220. Accordingly, negatively charged light conversion particles 330b move toward a positive electrode using the dispersion liquid 330a as a medium.

For example, when a voltage is not applied to the first electrode 210 and/or the second electrode 220 in an initial mode, as illustrated in FIG. 2, the light conversion particles 330b are uniformly dispersed in the dispersion liquid 330a. Accordingly, the receiving part 320 operates as a light blocking part.

Furthermore, when a voltage is applied to the first electrode 210 and/or the second electrode 220, as shown in FIG. 3, the light conversion particle 330b is moved in a direction toward the second electrode 220 in the dispersion liquid 330a, that is, the light conversion particle 330b is moved in one direction. Accordingly, the receiving part 320 operates as a light transmitting part.

Accordingly, the optical path control member according to the embodiment may be driven in two modes according to the user's surrounding environment. That is, when the user wants to transmit light only at a specific viewing angle, the receiving part may be driven as a light blocking part, or in an environment in which the user requires a wide viewing angle and high luminance, a voltage may be applied to drive the receiving unit as the light transmitting part.

Therefore, since the optical path control member according to the embodiment may be implemented in two modes according to the user's request, the optical path member may be applied regardless of the user's environment.

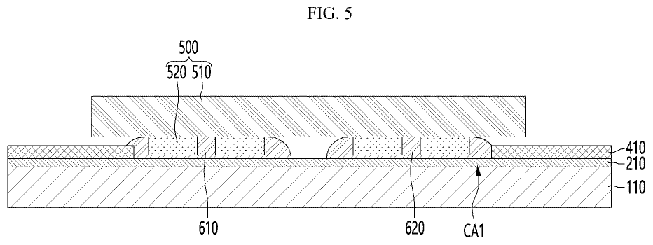

Hereinafter, connection between the connection regions CA1 and CA2 of the optical path control member and the printed circuit board 500 will be described with reference to FIGS. 4 and 5.

FIGS. 4 and 5 are combined cross-sectional views of an optical path control member and a printed circuit board according to an embodiment. Hereinafter, for convenience of explanation, the first connection region CA1 and the printed circuit board 500 will be mainly described. However, the following description is equally applied to the second connection region CA2.

Referring to FIG. 4, an adhesive layer 600 is disposed between the first connection region CA1 and the printed circuit board 500.

The first electrode 210 includes a first connection region CA1. The first connection region CA1 includes a first connection electrode 211. The first connection electrode 211 is defined as a region connected to the printed circuit board 500. The first connection electrode 211 may include a same material as the first electrode 210. The first connection electrode 211 is integrally formed with the first electrode 210.

The first connection electrode 211 may be disposed as one electrode in the first connection region CA1. That is, the first connection electrode 211 may be disposed as a single electrode, not a plurality of pattern electrodes. That is, a voltage is applied simultaneously to a plurality of receiving parts by one first electrode 210. That is, the first electrode is not separated into a plurality of first electrodes connected to a plurality of receiving parts, but is disposed as one electrode. Accordingly, the voltage applied by the one first electrode is transmitted to the plurality of receiving parts.

Accordingly, the first connection electrode 211 is also formed as one electrode connected to the one first electrode 210.

The adhesive layer 600 is disposed on the first connection electrode 211. The adhesive layer 600 is disposed in a single layer.

The adhesive layer 600 may include an isotropic conductive adhesive. Accordingly, the adhesive layer 600 may have conductivity in all directions.

The adhesive layer 600 may include a conductive paste. Specifically, the adhesive layer 600 may include a resin and conductive particles disposed inside the resin. For example, the adhesive layer 600 may include a conductive paste including silver (Ag) particles.

The printed circuit board 500 is disposed on the adhesive layer 600. Accordingly, the printed circuit board 500 and the first connection electrode 211 may be adhered to each other by the adhesive layer 600.

The printed circuit board 500 includes a base 510 and a pad part 520 disposed on the base 510. The pad part 520 includes a plurality of pad parts. Specifically, the pad part 520 includes a plurality of pad parts spaced apart from each other.

The plurality of pad parts 520 are in contact with the adhesive layer 600. Accordingly, the plurality of pad parts 520 are electrically connected to the first connection electrode 211 by the adhesive layer 600.

That is, the adhesive layer 600 contacts one first connection electrode 211 in the first connection region CA1. Also, the adhesive layer 600 contacts a plurality of pad parts 520 of the printed circuit board 500. Accordingly, one first connection electrode 211 is electrically connected to a plurality of pad parts 520. That is, the adhesive layer 600 electrically connects one first connection electrode 211 to a plurality of pad parts 520.

As described above, a voltage is applied to a plurality of receiving parts by one first electrode. Accordingly, even when the first connection electrode 211 and the plurality of pad parts are connected by an isotropic conductive adhesive, the first connection electrode 211 may be connected without a short circuit.

The adhesive layer 600 may include regions having different thicknesses. For example, the adhesive layer 600 includes an overlapping region OA and a non-overlapping region NOA. The overlapping region OA is a region in which the adhesive layer 600 and the pad part 520 overlap. Also, the non-overlapping region NOA is a region in which the adhesive layer 600 and the pad part 520 do not overlap.

A first thickness T1 of the overlapping region OA and a second thickness T2 of the non-overlapping region NOA may be different from each other. Specifically, the second thickness T2 may be greater than the first thickness T1.

That is, the adhesive layer 600 is disposed between the plurality of pad parts 520. Accordingly, the first thickness T1 may be less than the second thickness T2 by the thickness of the pad part 520.

The adhesion between the printed circuit board 500 and the first connection electrode 211 is improved by the non-overlapping region (NOA). Specifically, a contact area of the adhesive layer 600 contacting the printed circuit board 500 and the first connection electrode 211 is increased. Accordingly, the adhesion between the printed circuit board 500 and the first connection electrode 211 is improved.

Also, the conductivity of the printed circuit board 500 and the first connection electrode 211 is improved in the non-overlapping region (NOA). The adhesive layer 600 includes an isotropic conductive adhesive. Accordingly, the adhesive layer 600 may connect the pad part 520 and the first connection electrode 211 in the third direction 3D in the overlapping region OA. Also, the adhesive layer 600 may connect the pad part 520 and the first connection electrode 211 in the first direction 1D and the second direction 2D in the non-overlapping region NOA. Accordingly, the printed circuit board and the first connection electrode are electrically connected in a plurality of directions. Accordingly, the electrical connection between the printed circuit board and the first connection electrode is improved.

Meanwhile, the first connection region CA1 and the base 510 may be arranged to have different sizes. In detail, a width w1 of the first connection region CA1 may be different from a width w2 of the base 510. In more detail, the width w1 of the first connection region CA1 may be less than the width w2 of the base 510.

Accordingly, it is possible to prevent the first electrode 210 from being exposed to an outside. Accordingly, it is possible to prevent the first electrode 210 from being deformed by external impurities.

Also, the adhesive layer 600 and the base 510 may be disposed to have different sizes. Specifically, a width w3 of the adhesive layer 600 may be different from a width w2 of the base 510. More specifically, the width w3 of the adhesive layer 600 may be less than the width w2 of the base 510.

Accordingly, it is possible to prevent the adhesive layer 600 from being exposed to an outside. Accordingly, it is possible to prevent the occurrence of appearance defects due to the adhesive layer 600.

The optical path control member according to an embodiment includes an adhesive layer. The adhesive layer electrically connects the first electrode and the printed circuit board. Also, the adhesive layer electrically connects the second electrode and the printed circuit board.

The adhesive layer includes an isotropic conductive adhesive layer. Accordingly, the adhesive layer has conductivity in all directions. Accordingly, electrical connection characteristics between the first electrode and the pad portion of the printed circuit board are improved.

In addition, the adhesive layer is disposed as a single layer. Accordingly, the thickness of the adhesive layer is reduced. Accordingly, the thickness of the optical path control member is reduced.

Also, the adhesive layer includes regions having different thicknesses. Specifically, the adhesive layer is also disposed in a region between the pad parts. Accordingly, a contact area of the adhesive layer is increased. Accordingly, adhesion and electrical connection characteristics between the electrode and the printed circuit board are improved.

Also, the adhesive layer connects at least two pad parts with the first electrode. Therefore, current may be easily moved between the electrode and the printed circuit board 500.

Referring to FIG. 5, the adhesive layer 600 may include two or more adhesive layers spaced apart from each other. For example, the adhesive layer 600 may include a first adhesive layer 610 and a second adhesive layer 620 spaced apart from each other.

The first adhesive layer 610 may be connected to at least two pad parts 520. Also, the second adhesive layer 620 may be connected to at least two pad parts 520.

Accordingly, even if a defect occurs in any one of the plurality of pad parts, current may be stably moved by other pad part, and thus, the optical path control member according to the embodiment may have improved reliability.

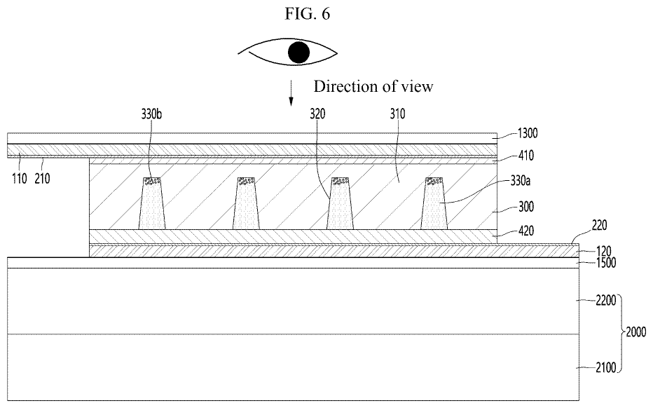

Hereinafter, a display device and a display device to which an optical path control member according to an embodiment is applied will be described with reference to FIGS. 6 to 10.

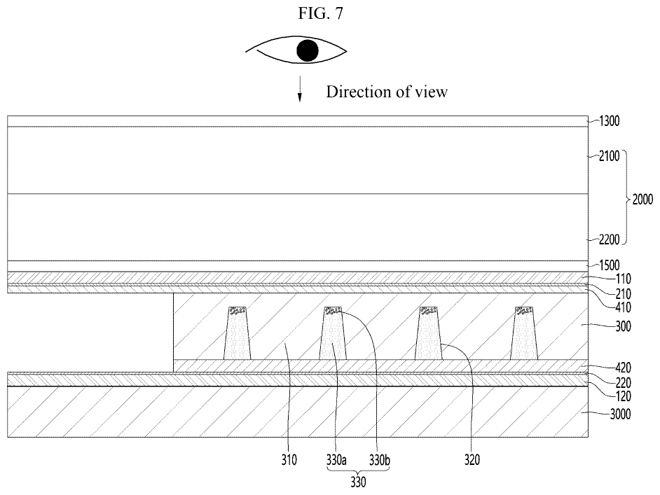

Referring to FIGS. 6 and 7, the optical path control member 1000 according to the embodiment may be disposed on or below the display panel 2000.

The display panel 2000 and the optical path control member 1000 may be disposed to be adhered to each other. For example, the display panel 2000 and the optical path control member 1000 may be adhered to each other via an adhesive layer 1500. The adhesive layer 1500 may be transparent. For example, the adhesive layer 1500 may include an adhesive or an adhesive layer including an optical transparent adhesive material.

The adhesive layer 1500 may include a release film. In detail, when adhering the optical path control member and the display panel, the optical path control member and the display panel may be adhered after the release film is removed.

The display panel 2000 may include a first base substrate 2100 and a second base substrate 2200. When the display panel 2000 is a liquid crystal display panel, the optical path control member may be formed under the liquid crystal panel. That is, when a surface viewed by the user in the liquid crystal panel is defined as an upper portion of the liquid crystal panel, the optical path control member may be disposed under the liquid crystal panel. The display panel 2000 may be formed in a structure in which the first base substrate 2100 including a thin film transistor (TFT) and a pixel electrode and the second base substrate 2200 including color filter layers are bonded to each other with a liquid crystal layer interposed therebetween.

In addition, the display panel 2000 may be a liquid crystal display panel of a color filter on transistor (COT) structure in which a thin film transistor, a color filter, and a black electrolyte are formed at the first base substrate 2100 and the second base substrate 2200 is bonded to the first base substrate 2100 with the liquid crystal layer interposed therebetween. That is, a thin film transistor may be formed on the first base substrate 2100, a protective film may be formed on the thin film transistor, and a color filter layer may be formed on the protective film. In addition, a pixel electrode in contact with the thin film transistor may be formed on the first base substrate 2100. At this point, in order to improve an aperture ratio and simplify a masking process, the black electrolyte may be omitted, and a common electrode may be formed to function as the black electrolyte.

In addition, when the display panel 2000 is the liquid crystal display panel, the display device may further include a backlight unit 3000 providing light from a rear surface of the display panel 2000.

That is, as shown in FIG. 6, the optical path control member may be disposed under the liquid crystal panel and on the backlight unit 3000, and the optical path control member may be disposed between the backlight unit 3000 and the display panel 2000.

Alternatively, as shown in FIG. 7, when the display panel 2000 is an organic light emitting diode panel, the optical path control member may be formed on the organic light emitting diode panel. That is, when the surface viewed by the user in the organic light emitting diode panel is defined as an upper portion of the organic light emitting diode panel, the optical path control member may be disposed on the organic light emitting diode panel. The display panel 2000 may include a self-luminous element that does not require a separate light source. In the display panel 2000, a thin film transistor may be formed on the first base substrate 2100, and an organic light emitting element in contact with the thin film transistor may be formed. The organic light emitting element may include an anode, a cathode, and an organic light emitting layer formed between the anode and the cathode. In addition, the second base substrate 2200 configured to function as an encapsulation substrate for encapsulation may be further included on the organic light emitting element.

In addition, although not shown in drawings, a polarizing plate may be further disposed between the optical path control member 1000 and the display panel 2000. The polarizing plate may be a linear polarizing plate or an external light reflection preventive polarizing plate. For example, when the display panel 2000 is a liquid crystal display panel, the polarizing plate may be the linear polarizing plate. Further, when the display panel 2000 is the organic light emitting diode panel, the polarizing plate may be the external light reflection preventing polarizing plate.

In addition, an additional functional layer 1300 such as an anti-reflection layer, an anti-glare, or the like may be further disposed on the optical path control member 1000. Specifically, the functional layer 1300 may be adhered to one surface of the first substrate 110 of the optical path control member. Although not shown in drawings, the functional layer 1300 may be adhered to the first substrate 110 of the optical path control member via an adhesive layer. In addition, a release film for protecting the functional layer may be further disposed on the functional layer 1300.

Further, a touch panel may be further disposed between the display panel and the optical path control member.

It is shown in the drawings that the optical path control member is disposed at an upper portion of the display panel, but the embodiment is not limited thereto, and the optical path control member may be disposed at various positions such as a position in which light is adjustable, that is, a lower portion of the display panel, or between a second substrate and a first substrate of the display panel, or the like.

In addition, it is shown in the drawings that the light conversion unit of the optical path control member according to the embodiment is in a direction parallel or perpendicular to an outer surface of the second substrate, but the light conversion unit is formed to be inclined at a predetermined angle from the outer surface of the second substrate. Through this, a moire phenomenon occurring between the display panel and the optical path control member may be reduced.

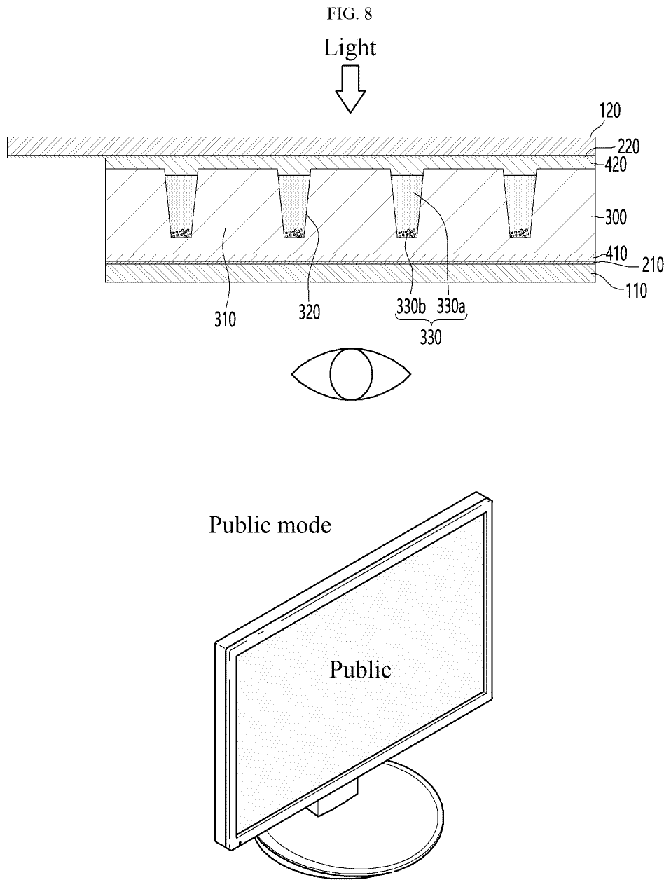

Referring to FIGS. 8 to 10, an optical path control member according to an embodiment may be applied to various display devices.

Referring to FIGS. 8 to 10, the optical path control member according to an embodiment may be applied to a display device that displays a display.

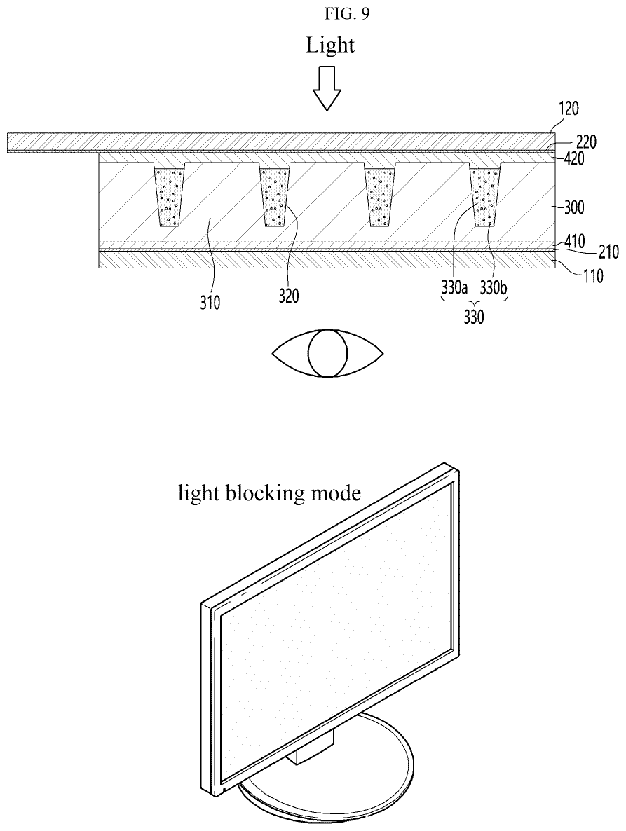

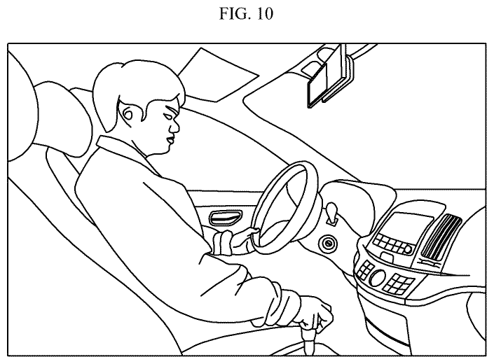

For example, when power is applied to the optical path control member as shown in FIG. 8, the receiving part functions as the light transmitting part, so that the display device may be driven in the public mode, and when power is not applied to the optical path control member as shown in FIG. 9, the receiving part functions as the light blocking part, so that the display device may be driven in the light blocking mode.

Accordingly, a user may easily drive the display device in a privacy mode or a normal mode according to application of power.

Light emitted from the backlight unit or the self-luminous element may move from the first substrate toward the second substrate. Alternatively, the light emitted from the backlight unit or the self-luminous element may also move from the second substrate toward the first substrate.

In addition, referring to FIG. 10, the display device to which the optical path control member according to the embodiment is applied may also be applied inside a vehicle.

For example, the display device including the optical path control member according to the embodiment may display a video confirming information of the vehicle and a movement route of the vehicle. The display device may be disposed between a driver seat and a passenger seat of the vehicle.

In addition, the optical path control member according to the embodiment may be applied to a dashboard that displays a speed, an engine, an alarm signal, and the like of the vehicle.

In addition, the optical path control member according to the embodiment may be applied to a front glass (FG) of the vehicle or right and left window glasses.

The characteristics, structures, effects, and the like described in the above-described embodiments are included in at least one embodiment of the present invention, but are not limited to only one embodiment. Furthermore, the characteristic, structure, and effect illustrated in each embodiment may be combined or modified for other embodiments by a person skilled in the art. Accordingly, it is to be understood that such combination and modification are included in the scope of the present invention.

In addition, embodiments are mostly described above, but the embodiments are merely examples and do not limit the present invention, and a person skilled in the art may appreciate that several variations and applications not presented above may be made without departing from the essential characteristic of embodiments. For example, each component specifically represented in the embodiments may be varied. In addition, it should be construed that differences related to such a variation and such an application are included in the scope of the present invention defined in the following claims.

1. An optical path control member comprising:
a first substrate;
a first electrode disposed on the first substrate and including a first connection electrode;
a second substrate disposed on the first substrate;
a second electrode disposed under the second substrate and including a second connection electrode;
a light conversion unit disposed between the first electrode and the second electrode;
an adhesive layer disposed on the first connection electrode and the second connection electrode; and
a circuit board disposed on the adhesive layer and electrically connected to the first connection electrode and the second connection electrode,
wherein the adhesive layer includes an isotropic conductive adhesive layer.

2. The optical path control member of claim 11, wherein the adhesive layer is disposed as a single layer.

3. The optical path control member of claim 11, wherein the light conversion unit includes a plurality of receiving parts separated by a partition wall part,
wherein a dispersion liquid and light conversion particles dispersed by the dispersion liquid are disposed within the plurality of receiving parts,
wherein the light conversion particles move by applying a voltage, and
wherein the plurality of receiving parts are connected to one first electrode.

4. The optical path control member of claim 3, wherein the printed circuit board includes a base and a plurality of pad parts disposed on the base and spaced apart from each other, and
wherein the plurality of pad parts include a plurality of first pad parts connected to the first connection electrode, and a plurality of second pad parts connected to the second connection electrode, and
wherein the plurality of first pad parts are disposed in the open region.

5. The optical path control member of claim 4, wherein the adhesive layer includes an overlapping region overlapping the plurality of first pad parts and a non-overlapping region non-overlapping the plurality of first pad parts.

6. The optical path control member of claim 5, wherein the adhesive layer is disposed between the plurality of first pad parts.

7. The optical path control member of claim 5, wherein a first thickness of the overlapping region is smaller than a second thickness of the non-overlapping region.

8. A display device comprising:
a panel including at least one of a display panel and a touch panel; and
the optical path control member of claim 1 disposed on or under the panel.

9. The display device of claim 8, wherein the panel includes a backlight unit and a liquid crystal display panel, and
wherein the optical path control member is disposed between the backlight unit and the liquid crystal display panel, and
wherein light emitted from the backlight unit moves from the second substrate toward the first substrate.

10. The display device of claim 8, wherein the panel includes an organic light emitting diode panel,
wherein the optical path control member is disposed on the organic light emitting diode panel, and
wherein light emitted from the panel moves from the second substrate toward the first substrate.

11. The optical path control member of claim 1, comprising:
a buffer layer disposed between the first electrode and the light conversion unit and including an open region,
wherein the first connection electrode overlaps the open region in a thickness direction of the first substrate, and
wherein the adhesive layer is disposed in the open region.

12. The optical path control member of claim 11, wherein the buffer layer includes a first portion that overlaps the light conversion unit along the thickness direction, and a second portion that does not overlap the light conversion unit, and
wherein the open region is provided in the second portion of the buffer layer.

13. The optical path control member of claim 11, comprising:
an adhesive member disposed between the second electrode and the light conversion unit, and wherein a width of the adhesive member is same as a width of the light conversion unit.

14. The optical path control member of claim 11, wherein the second connection electrode does not overlap the adhesive member along the thickness direction.

15. The optical path control member of claim 4, wherein the plurality of first pad parts are commonly connected to a single first connection electrode through the adhesive layer disposed in the open region.

16. The optical path control member of claim 4, wherein the plurality of second pad parts are commonly connected to a single second connection electrode.

17. The optical path control member of claim 15, wherein the adhesive layer includes a first adhesive layer in the open region, and a second adhesive layer disposed in the open region and spaced apart from the first adhesive layer.

18. The optical path control member of claim 17, wherein the plurality of first pad parts include a plurality of first-first pad parts connected to the first connection electrode through the first adhesive layer, and a plurality of first-second pad parts connected to the first connection electrode through the second adhesive layer.

19. The optical path control member of claim 18, wherein the plurality of first-first pad parts and the plurality of first-second pad parts are commonly connected to a same first connection electrode through the first adhesive layer and the second adhesive layer spaced apart from each other.
